(19) United States
(12) Patent Application Publication
(10) Pub. No.: US 2021/0292620 A1
(43) Pub. Date: Sep. 23, 2021

(54) Heat Dissipation Adhesive Film and Display Device Including the Same

(71) Applicant: LG Display Co., Ltd., Seoul (KR)

(72) Inventor: TaeSoo JO, Paju-si (KR)

(21) Appl. No.: 17/139,554

(22) Filed: Dec. 31, 2020

(30) Foreign Application Priority Data
Nov. 8, 2019 (KR) 10-2019-0142679

(51) Int. Cl. C09J 175/04; C09J 7/35; C09J 7/25; C09J 7/24; C09J 133/08

(52) U.S. Cl. CPC C09J 175/04; C09J 7/35; C09J 133/08; C09J 7/241; C09J 7/25

(57) ABSTRACT

The present disclosure relates to a heat dissipation adhesive film and a display device including the same. The heat dissipation adhesive film according to an exemplary embodiment of the present disclosure includes a base film, a first adhesive film on a lower surface of the base film, and a second adhesive film on an upper surface of the base film, and the first adhesive film or the second adhesive film includes an adhesive resin and heat dissipation beads dispersed in the adhesive resin. Accordingly, the heat dissipation characteristic is improved and, at the same time, the substrate or the back cover may be reusable.

### CROSS-REFERENCE TO RELATED APPLICATION

This application claims the priority of Republic of Korea Patent Application No. 10-2019-0142679 filed on Nov. 8, 2019, in the Korean Intellectual Property Office, the disclosure of which is incorporated by reference in its entirety.

### BACKGROUND

### Field of Technology

The present disclosure relates to a heat dissipation adhesive film and a display device including the same, and more particularly, to a heat dissipation adhesive film which is capable of implementing a rework characteristic while improving a heat dissipation characteristic and a display device including the same.

### Description of the Related Art

Recently, as it enters the full-fledged information era, a display field which visually expresses electrical information signals has been rapidly developed and in response to this, various display apparatuses having excellent performance such as thin-thickness, light weight, and low power consumption have been developed. Specific examples of the above-mentioned display apparatus include a liquid crystal display device (LCD), an organic light emitting display device (OLED), and an electroluminescence display device such as a quantum-dot light emitting display device (QLED).

Further, recently, a flexible display device such as a bendable display device or a foldable display device is being developed. The flexible display device may be implemented by forming a display unit and wiring lines on a flexible substrate such as plastic which is a flexible material and applying a back cover to a rear surface of the substrate to protect a flexible display panel. The flexible display device is capable of displaying images even though it is bent like a paper, may be easily carried when the flexible display device is folded, and implement a large screen when the flexible display is extended. Therefore, the flexible display device may be applied to various fields such as a television and a monitor as well as mobile equipment such as a mobile phone, an electronic book, and an electronic newspaper.

### SUMMARY

An object to be achieved by the present disclosure is to provide a heat dissipation adhesive film disposed between a back cover and a display panel and including heat dissipation beads to improve a heat dissipation characteristic, and a display device including the same.

Another object to be achieved by the present disclosure is to provide a heat dissipation adhesive film which is easily removed from the back cover and the display panel by lowering the adhesiveness of the heat dissipation adhesive film by being stretched, and a display device including the same.

Still another object to be achieved by the present disclosure is to provide a heat dissipation adhesive film in which rework of a back cover and a display panel is allowed, and a display device including the same.

Objects of the present disclosure are not limited to the above-mentioned objects, and other objects, which are not mentioned above, may be clearly understood by those skilled in the art from the following descriptions.

A heat dissipation adhesive film according to an exemplary embodiment of the present disclosure includes a base film; a first adhesive film on a lower surface of the base film, and a second adhesive film on an upper surface of the base film, and the first adhesive film or the second adhesive film includes an adhesive resin and heat dissipation beads dispersed in the adhesive resin.

A display device according to an exemplary embodiment of the present disclosure includes a substrate; a light emitting diode on the substrate, a back cover below the substrate, and a heat dissipation adhesive film which bonds the back cover and the substrate, the heat dissipation adhesive film includes a base film; a first adhesive film between the base film and the back cover, and a second adhesive film between the base film and the substrate, and the first adhesive film or the second adhesive film includes an adhesive resin and heat dissipation beads dispersed in the adhesive resin.

Other detailed matters of the embodiments are included in the detailed description and the drawings.

According to the present disclosure, heat generated in the display device may be easily discharged to the outside by the heat dissipation adhesive film including heat dissipation beads.

According to the present disclosure, the adhesiveness of the heat dissipation adhesive film is reduced by stretching so that the heat dissipation adhesive film may be easily released from the back cover and the substrate.

According to the present disclosure, the heat dissipation adhesive film may be easily removed from the back cover and the display panel without causing a damage of the back cover and the display panel so that the back cover and the display panel may be reusable.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view of a display device according to an exemplary embodiment of the present disclosure;

FIG. 2 is a cross-sectional view of a heat dissipation adhesive film according to an exemplary embodiment of the present disclosure;

FIG. 3 is a cross-sectional view when a heat dissipation adhesive film according to an exemplary embodiment of the present disclosure is stretched;

FIG. 4 is an image obtained by photographing a surface of a heat dissipation adhesive film according to an exemplary embodiment of the present disclosure;

FIG. 5 is a cross-sectional view of a heat dissipation adhesive film according to another exemplary embodiment of the present disclosure;

FIGS. 6A to 6C are temperatures of black spot patterns of a display device to which adhesive members according to Comparative Embodiments of Related Art and Embodiment are applied;

FIGS. 7A and 7B are cross-sectional views of an adhesive member according to Comparative Embodiments;

FIGS. 8A to 8C are restoring force evaluation results of adhesive members according to Comparative Embodiments and Embodiment; and

FIG. 9 is a cross-sectional view of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to exemplary embodiment disclosed below but will be implemented in various forms. The exemplary embodiments are provided by way of example only so that a person of ordinary skilled in the art may fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure may be partially or entirely bonded to or combined with each other and may be interlocked and operated in technically various ways, and the embodiments may be carried out independently of or in association with each other.

Hereinafter, the present disclosure will be described in detail with reference to the drawings.

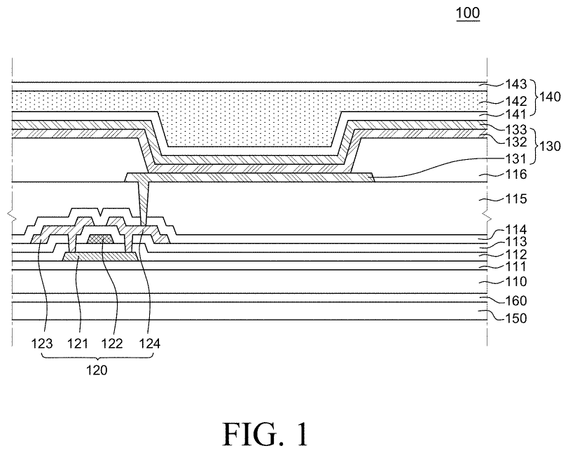

FIG. 1 is a cross-sectional view of a display device according to an exemplary embodiment of the present disclosure.

Referring to FIG. 1, the display device 100 includes a substrate 110, a transistor 120, a light emitting diode 130, an encapsulating unit 140, a back cover 150, and a heat dissipation adhesive film 160. Hereinafter, for the convenience of description, the display device 100 according to an exemplary embodiment of the present disclosure will be described as an organic light emitting display device, but it is not limited thereto. That is, the display device 100 may also be configured as a liquid crystal display device.

In the meantime, the display device may be configured by a top emission type or a bottom emission type, depending on an emission direction of light which is emitted from the light emitting diode.

According to the top emission type, light emitted from the light emitting diode is emitted to an upper portion of the substrate on which the light emitting diode is formed. In the case of the top emission type, a reflective layer may be formed below the anode to allow the light emitted from the light emitting diode to travel to the upper portion of the substrate, that is, toward the cathode.

According to the bottom emission type, light emitted from the light emitting diode is emitted to a lower portion of the substrate on which the light emitting diode is formed. In the case of the bottom emission type, the anode may be formed of a transparent conductive material to allow the light emitted from the light emitting diode to travel to the lower portion of the substrate and the cathode may be formed of the metal material having a high reflectance. Further, in the case of the bottom emission type, the display device may include an encapsulating substrate 960 over the substrate 110 on which the transistor and the light emitting diode is formed. Also, at least one adhesive layer may be disposed between the substrate 110 and the encapsulating substrate 960, which may seal the transistor and the light emitting diode on the substrate.

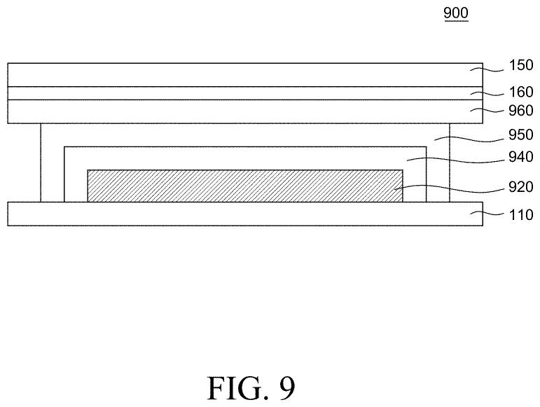

Hereinafter, for the convenience of description, the description will be made by assuming that the display device 100 according to the exemplary embodiment of the present disclosure is a top emission type display device 100. That is, the display device 100 according to the exemplary embodiment of the present disclosure may emit light toward a front surface of the display device of FIG. 1, but the present disclosure is not limited thereto. If the display device is the bottom emission type, the back cover 150 of FIG. 1 may be disposed on the encapsulating substrate 960 and the heat dissipation adhesive film 160 of FIG. 1 may be disposed between the encapsulating substrate 960 and the back cover 150. A detailed description thereof will be made below with reference to FIG. 9.

The substrate 110 is a substrate which supports and protects a plurality of components of the display device 100. The substrate 110 may be formed of a plastic material having flexibility. When the substrate 110 is formed of a plastic material, for example, the substrate may be formed of polyimide (PI), but it is not limited thereto.

A buffer layer 111 is disposed on the substrate 110. The buffer layer 111 may improve adhesiveness between layers formed on the buffer layer 111 and the substrate 110 and may block alkali components leaking from the substrate 110. The buffer layer 111 may be formed of a single layer of silicon nitride (SiNx) or silicon oxide (SiOx) or a multi-layer of silicon nitride (SiNx) and/or silicon oxide (SiOx). The buffer layer 111 may be omitted in other embodiments. For example, the buffer layer 111 may be omitted based on a type and a material of the substrate 110 and a structure and a type of the transistor 120.

The transistor 120 is disposed on the buffer layer 111 to drive the light emitting diode 130. The transistor 120 includes an active layer 121, a gate electrode 122, a source electrode 123, and a drain electrode 124. The transistor 120 illustrated in FIG. 1 is a driving transistor and is a top gate type thin film transistor in which the gate electrode 122 is disposed on the active layer 121. However, it is not limited thereto and the transistor 120 may be implemented as a bottom gate type thin film transistor.

The active layer 121 of the transistor 120 is disposed on the buffer layer 111. When the transistor 120 is driven, a channel is formed in the active layer 121. The active layer 121 may be formed of an oxide semiconductor or amorphous silicon (a-Si), polycrystalline silicon (poly-Si), an organic semiconductor, or the like.

A gate insulating layer 112 is disposed on the active layer 121. The gate insulating layer 112 may be formed as a single layer of silicon nitride (SiNx) or silicon oxide (SiOx) which is an inorganic material or a multi-layer of silicon nitride (SiNx) and/or silicon oxide (SiOx). In the gate insulating layer 112, a contact hole through which the source electrode 123 and the drain electrode 124 are in contact with a source area and a drain area of the active layer 121, respectively, is formed. The gate insulating layer 112 may be formed on the entire surface of the flexible substrate 110 as illustrated in FIG. 1, or patterned to have the same width as the gate electrode 122, but is not limited thereto.

The gate electrode 122 is disposed on the gate insulating layer 112. The gate electrode 122 is disposed on the gate insulating layer 112 so as to overlap a channel area of the active layer 121. The gate electrode 122 may be any one of various metal materials, for example, any one of molybdenum (Mo), aluminum (Al), chrome (Cr), gold (Au), titanium (Ti), nickel (Ni), neodymium (Nd), or copper (Cu) or an alloy of two or more of them, or a multi-layer thereof.

An interlayer insulating layer 113 is disposed on the gate electrode 122. The interlayer insulating layer 113 may be formed as a single layer of silicon nitride (SiNx) or silicon oxide (SiOx) which is an inorganic material or a multi-layer of silicon nitride (SiNx) and/or silicon oxide (SiOx). In the interlayer insulating layer 113, a contact hole through which the source electrode 123 and the drain electrode 124 are in contact with the source area and the drain area of the active layer 121, respectively, is formed.

The source electrode 123 and the drain electrode 124 are disposed on the interlayer insulating layer 113. The source electrode 123 and the drain electrode 124 are electrically connected to the active layer 121 through the contact holes of the gate insulating layer 112 and the interlayer insulating layer 113. The source electrode 123 and the drain electrode 124 may be formed of any one of various metal materials, for example, any one of molybdenum (Mo), aluminum (Al), chrome (Cr), gold (Au), titanium (Ti), nickel (Ni), neodymium (Nd), or copper (Cu) or an alloy of two or more of them, or a multi-layer thereof.

For the convenience of description, in FIG. 1, only a driving transistor, among various transistors 120 included in the light emitting display device 100, is illustrated, but other transistors such as a switching transistor may also be disposed.

Referring to FIG. 1, a passivation layer 114 for protecting the transistor 120 is disposed on the transistor 120. A contact hole which exposes the drain electrode 124 of the transistor 120 is formed on the passivation layer 114. Even though in FIG. 1, the contact hole which exposes the drain electrode 124 is formed in the passivation layer 114, a contact hole which exposes the source electrode 123 may also be formed. The passivation layer 114 may be formed as a single layer of silicon nitride (SiNx) or silicon oxide (SiOx) or a multi-layer of silicon nitride (SiNx) and/or silicon oxide (SiOx). However, the passivation layer 114 may be omitted depending on the exemplary embodiment.

An over coating layer 115 is disposed on the passivation layer 114 to planarize an upper portion of the transistor 120. A contact hole which exposes the drain electrode 124 of the transistor 120 is formed in the over coating layer 115. Even though in FIG. 1, the contact hole which exposes the drain electrode 124 is formed in the over coating layer 115, a contact hole which exposes the source electrode 123 may also be formed. The over coating layer 115 may be formed of any one of acrylic resin, epoxy resin, phenol resin, polyamide resin, polyimide resin, unsaturated polyester resin, polyphenylen resin, polyphenylene sulfide resin, benzocyclobutene, or photoresist, but is not limited thereto.

Referring to FIG. 1, the light emitting diode 130 is disposed on the over coating layer 115. The light emitting diode 130 includes a first electrode 131 which is formed on the over coating layer 115 to be electrically connected to the drain electrode 124 of the transistor 120, a light emitting layer 132 disposed on the first electrode 131, and a second electrode 133 formed on the light emitting layer 132. Here, the first electrode 131 may be an anode electrode and the second electrode 133 may be a cathode electrode.

The first electrode 131 is disposed on the over coating layer 115 to be electrically connected to the drain electrode 124 through contact holes formed in the passivation layer 114 and the over coating layer 115. The first electrode 131 may be formed of a conductive material having a high work function to supply holes to the light emitting layer 132. For example, the first electrode 131 may be formed of transparent conductive oxide such as indium tin oxide (ITO), indium zinc oxide (IZO), indium tin zinc oxide (ITZO), zinc oxide (ZnO), or tin oxide (TO)-based, but is not limited thereto.

In the meantime, when the display device 100 is a top emission type display device, the light emitting diode 130 is also configured as a top emission type. In the case of the top emission type, a reflective layer which reflects light emitted from the light emitting layer 132 toward the second electrode 133 may be disposed below the first electrode 131. The reflective layer may be formed of a material having an excellent reflectance such as silver (Ag) or Ag alloy, but is not limited thereto.

Even though in FIG. 1, it is illustrated that the first electrode 131 is electrically connected to the drain electrode 124 of the transistor 120 through a contact hole, the first electrode 131 may also be configured to be electrically connected to the source electrode 123 of the transistor 120 through a contact hole by the type of the transistor 120 and a design method of the driving circuit.

A bank 116 is disposed on the first electrode 131 and the over coating layer 115. The bank 116 may cover a part of the first electrode 131 of the light emitting diode 130 to define an emission area. The bank 116 may be formed of an organic material. For example, the bank 116 may be formed of polyimide resin, acrylic resin, or benzocyclobutene (BCB) resin, but is not limited thereto.

The light emitting layer 132 is disposed on the first electrode 131. The light emitting layer 132 is a layer for emitting light having a specific color and may include one of a red light emitting layer, a green light emitting layer, a blue light emitting layer, or a white light emitting layer. Further, the light emitting layer 132 may further include various layers such as a hole transport layer, a hole injection layer, a hole blocking layer, an electron injection layer, an electron blocking layer, or an electron transport layer.

The second electrode 133 is disposed on the light emitting layer 132. The second electrode 133 supplies electrons to the light emitting layer 132. The second electrode 133 may be formed of a conductive material having a low work function. For example, the second electrode 133 may be formed of opaque conductive metals such as magnesium (Mg), silver (Ag), aluminum (Al), or calcium (Ca), or an alloy thereof. Alternatively, the second electrode 133 may be formed of transparent conductive oxide such as indium tin oxide (ITO), indium zinc oxide (IZO), indium tin zinc oxide (ITZO), zinc oxide (ZnO), or tin oxide (TO)-based or ytterbium (Yb) alloy. Alternatively, the second electrode 133 may be formed of a metal material having a very thin thickness. However, the second electrode 133 is not limited to the above-mentioned materials.

In the meantime, when the display device 100 is a top emission type display device, the second electrode 133 may have a transparent or semi-transmissive property to allow light emitted from the light emitting layer 132 to pass out the second electrode 133 to be emitted to the outside.

Referring to FIG. 1, the encapsulating unit 140 is disposed on the light emitting diode 130. For example, the encapsulating unit 140 is disposed on the second electrode 133 so as to cover the light emitting diode 130. The encapsulating unit 140 protects the light emitting diode 130 from moisture infiltrating from the outside of the light emitting display device 100. The encapsulating unit 140 includes a first encapsulating layer 141, a foreign material cover layer 142, and a second encapsulating layer 143.

The first encapsulating layer 141 is disposed on the second electrode 133 to suppress the permeation of moisture or oxygen. The first encapsulating layer 141 may be formed of an inorganic material such as silicon nitride (SiNx), silicon oxy nitride (SiNxOy), or aluminum oxide (AlyOz), but is not limited thereto.

The foreign material cover layer 142 is disposed on the first encapsulating layer 141 to planarize the surface of the first encapsulating layer 141. Further, the foreign material cover layer 142 may cover foreign materials or particles which may be generated during a manufacturing process. The foreign material cover layer 142 may be formed of an organic material, such as silicon oxy carbon (SiOxCz), acryl-based or epoxy-based resin, but is not limited thereto.

The second encapsulating layer 143 is disposed on the foreign material cover layer 142 and suppresses the permeation of moisture or oxygen together with the first encapsulating layer 141. The second encapsulating layer 143 may be formed of an inorganic material such as silicon nitride (SiNx), silicon oxynitride (SiNxOy), silicon oxide (SiOx), or aluminum oxide (AlyOz), but is not limited thereto. The second encapsulating layer 143 may be formed of the same material as the first encapsulating layer 141 or formed of a different material.

The back cover 150 is disposed below the substrate 110. The back cover 150 may be disposed to support the flexible substrate 110. The back cover 150 supports the substrate 110 to supplement a rigidity of the substrate 110. The back cover 150 may be formed of a plastic thin film formed of polyimide, polyethylene naphthalate (PEN), polyethylene terephthalate (PET), polymers, or a combination of the polymers. Alternatively, the back cover 150 may be formed of a metal material such as copper (Cu), aluminum (Al), iron (Fe), molybdenum (Mo), titanium (Ti), gold (Au), or silver (Ag). However, the material of the back cover 150 is not limited thereto.

When the substrate 110 is formed of a plastic material such as polyimide, due to the flexible property, a separate component for supporting the substrate 110 may be necessary. Therefore, a support substrate which is formed of glass is disposed below the substrate 110 to perform the manufacturing process of the display device 100. After completing the manufacturing process, the support substrate is separated to be released and the back cover 150 may be disposed below the substrate 110. That is, in order to support the substrate 110 after releasing the support substrate, the back cover 150 may be disposed below the substrate 110.

The heat dissipation adhesive film 160 may be disposed between the substrate 110 and the back cover 150. The heat dissipation adhesive film 160 may be a double-sided adhesive member to bond the display panel and the back cover 150. Here, the display panel may refer to the substrate 110 and components disposed above the substrate 110, among components of the display device 100. That is, the heat dissipation adhesive film 160 may be a film which bonds the substrate 110 and the back cover 150. At this time, the heat dissipation adhesive film 160 may be disposed on the entire surfaces of between the substrate 110 and the back cover 150. That is, the heat dissipation adhesive film 160 is configured by a double-sided adhesive film and is disposed on the entire surfaces of the substrate 110 and the back cover 150 so that the adhesiveness reliability between the substrate 110 and the back cover 150 may be improved.

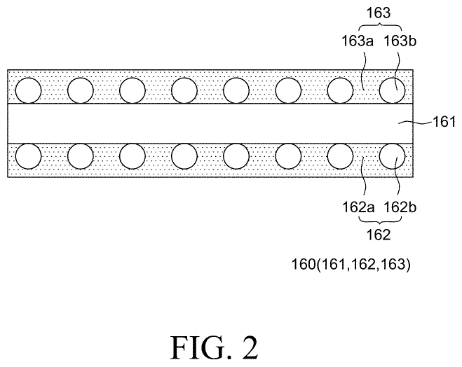

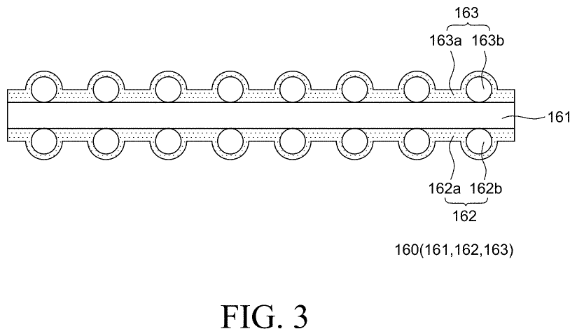

The heat dissipation adhesive film 160 may be a stretchable film which may be stretched. Specifically, the adhesiveness of the heat dissipation adhesive film 160 before and after being stretched may be different. Specifically, the adhesiveness after stretching the heat dissipation adhesive film 160 may be less than the adhesiveness before stretching the heat dissipation adhesive film 160. Therefore, the back cover 150 and the substrate 110 may be easily separated by the lowering of the adhesiveness between the heat dissipation adhesive film 160 and the back cover 150 or between the heat dissipation adhesive film 160 and the substrate 110. Accordingly, the display panel and the back cover 150 may be reworked. Hereinafter, the heat dissipation adhesive film 160 will be described in more detail with reference to FIGS. 2 and 3 together.

FIG. 2 is a cross-sectional view of a heat dissipation adhesive film 160 according to an exemplary embodiment of the present disclosure. FIG. 3 is a cross-sectional view when a heat dissipation adhesive film 160 according to an exemplary embodiment of the present disclosure is stretched.

First, referring to FIG. 2, the heat dissipation adhesive film 160 includes a base film 161, a first adhesive film 162, and a second adhesive film 163.

The base film 161 is a film for supporting the heat dissipation adhesive film 160 and maintaining the rigidity. The base film 161 may be formed of a material which is capable of being stretched while maintaining the rigidity of the heat dissipation adhesive film 160. For example, the base film 161 may include urethane-based or butadiene-based rubber. Specifically, the base film 161 may be configured by thermoplastic polyurethane (TPU), but is not limited thereto.

The first adhesive film 162 is disposed below the base film 161. The first adhesive film 162 may be an area of the heat dissipation adhesive film 160 which faces the back cover 150. The first adhesive film 162 has adhesiveness to be bonded to the back cover 150. The first adhesive film 162 may include an adhesive resin 162a and heat dissipation beads 162b which are dispersed in the adhesive resin 162a.

The adhesive resin 162a gives the adhesiveness to the first adhesive film 162. The adhesive resin 162a may be formed of a material which is capable of being stretched while having adhesiveness. For example, the adhesive resin 162a may include acrylate-based or urethane-based pressure sensitive adhesives (PSA).

To be more specific, the adhesive resin 162a is 100 parts by weight of an acrylate-based resin containing 20% or more of a carboxyl group or a hydroxyl group solid content, 0.093 parts by weight of a silane-based coupling agent, 0.20 parts by weight of an isocyanate-based curing agent having 40% or more of a solid content, and 0.15 parts by weight of an epoxy-based curing agent having 5% of a solid content. Here, a carboxyl group or a hydroxyl group is a component for implementing the adhesiveness of the adhesive resin 162a. The higher the content thereof, the higher the adhesiveness. The epoxy-based curing agent is a component for implementing modulus and the higher the content thereof, the higher the modulus.

The heat dissipation bead 162b may improve the heat dissipation characteristic of the first adhesive film 162. The heat dissipation bead 162b may include a material having excellent heat dissipation characteristic. For example, the heat dissipation bead 162b may include zinc oxide (ZnO), silicon carbide (SiC), magnesium oxide (MgO), boron nitride (BN), aluminum hydroxide (Al₂(OH)₃), aluminum oxide (Al₂O₃), silicon nitride (Si3N4), graphine, carbon nanotube (CNT), graphite, or a combination thereof.

In the meantime, even though in FIG. 2, eight heat dissipation beads 162b have been illustrated for the convenience of description, it is not limited thereto. Further, even though in FIG. 2, the heat dissipation beads 162b are illustrated to be spaced apart from each other with a constant interval while being in contact with the base film 161, substantially, the heat dissipation beads 162b may be randomly dispersed in the adhesive resin 162a.

The second adhesive film 163 is disposed above the base film 161. The second adhesive film 163 may be an area of the heat dissipation adhesive film 160 which faces the substrate 110. The second adhesive film 163 has adhesiveness to be bonded to the substrate 110. The second adhesive film 163 may include an adhesive resin 163a and heat dissipation beads 163b which are dispersed in the adhesive resin 163a. The adhesive resin 163a and the heat dissipation beads 163b of the second adhesive film 163 may have the same configuration as the adhesive resin 162a and the heat dissipation beads 162b of the first adhesive film 162.

The heat dissipation adhesive film 160 includes the heat dissipation beads 162b and 163b to easily discharge heat generated in the display device 100. Further, when the heat dissipation adhesive film 160 is stretched, an adhesive surface area between the adhesive resins 162a and 163a and the substrate 110 or the back cover 150 may be reduced due to the heat dissipation beads 162b and 163b. Accordingly, the adhesiveness of the heat dissipation adhesive film 160 after being stretched may be reduced due to the heat dissipation beads 162b and 163b.

Specifically, when the heat dissipation adhesive film 160 is released from the substrate 110 (the encapsulating substrate 960 of FIG. 9 in a case of the bottom emission type) or the back cover 150, an end of the heat dissipation adhesive film 160 is pulled to stretch the heat dissipation adhesive film 160. As the heat dissipation adhesive film 160 is stretched, the adhesive surface area is reduced, and the adhesiveness is reduced so that the heat dissipation adhesive film 160 may be easily separated from the substrate 110 or the back cover 150. Specifically, the heat dissipation adhesive film 160 is removed without causing damage of the substrate 110 and the back cover 150 to implement a rework characteristic of the display panel and the back cover 150. Hereinafter, the characteristic of the heat dissipation adhesive film 160 will be described in detail with reference to FIG. 3 which illustrates a stretched state of the heat dissipation adhesive film 160 of FIG. 2 which is pulled to the left or right side.

Referring to FIG. 3, as the heat dissipation adhesive film 160 is stretched, the base film 161, the adhesive resin 162a of the first adhesive film 162, and the adhesive resin 163a of the second adhesive film 163 are stretched, a length may be increased as compared with an initial state of FIG. 2. At this time, the heat dissipation beads 162b and 163b are formed of particles harder than the base film 161 and the adhesive resins 162a and 163a so that shapes of the heat dissipation beads are hardly deformed due to the stretching. That is, when the heat dissipation adhesive film 160 is stretched, the heat dissipation beads 162b and 163b maintain the same thickness, but the adhesive resins 162a and 163a are stretched so that the thickness thoseof may be reduced.

Specifically, the thickness reduction of the adhesive resins 162a and 163a may be the most significant between the adjacent heat dissipation beads 162b and 163b. In other words, with respect to a vertical direction of FIG. 3, heights of the adhesive films 162 and 163 in an area where the adhesive resins 162a and 163a and the heat dissipation beads 162b and 163b do not overlap may be less than heights of the adhesive films 162 and 163 in an overlapping area where the adhesive resins 162a and 163a and the heat dissipation beads 162b and 163b overlap. That is, the adhesive resins 162a and 163a are stretched so that the thickness is reduced. However, the overlapping area of the adhesive resins 162a and 163a and the heat dissipation beads 162b and 163b may protrude more than the area where the adhesive resins and the heat dissipation beads do not overlap, due to the thickness of the heat dissipation beads 162b and 163b. Accordingly, surfaces of the first adhesive film 162 and the second adhesive film 163 after being stretched may have an uneven shape due to the heat dissipation beads 162b and 163b.

Due to the height difference on the surfaces of the adhesive films 162 and 163, a contact area between the first adhesive film 162 and the back cover 150 and a contact area between the second adhesive film 163 and the substrate 110 may be reduced. That is, when the heat dissipation adhesive film 160 is stretched, an adhesive surface area between the heat dissipation adhesive film 160 and the substrate 110 or the back cover 150 may be reduced due to the heat dissipation beads 162b and 163b. Therefore, the heat dissipation adhesive film 160 may be easily separated from the substrate 110 or the back cover 150. In other words, the adhesiveness of the heat dissipation adhesive film 160 with the substrate 110 or the back cover 150 is reduced after being stretched so that the heat dissipation adhesive film 160 may be easily released. Accordingly, the substrate 110 and the back cover 150 may be reused after being separated so that the rework characteristic may be improved.

As an adhesive member which bonds the display panel and the back cover, a foam tape has been generally used. At this time, the foam tape may be attached only to an area corresponding to an edge of the display panel. Accordingly, when the foam tape is exposed to a high temperature/high humidity environment or is applied with an external impact, the foam tape is released from the display panel or the back cover, so that a problem may occur in the adhesive reliability between the display panel and the back cover. Further, when the display panel and the back cover are separated, the foam tape needs to be cut using wire-cutting. However, in this case, the display panel is damaged so that it is difficult to reuse the display panel. Further, the lifespan of the light emitting diode may be shortened due to the heat generated when the display device is used. Accordingly, a display quality may be degraded, such as an afterimage generated on the display device.

The display device 100 according to the present disclosure may use the heat dissipation adhesive film 160 to bond the substrate 110 of the display panel and the back cover 150. At this time, the heat dissipation adhesive film 160 may be disposed so as to correspond to an overall area of the substrate 110 (the encapsulating substrate 960 of FIG. 9 in a case of the bottom emission type) or the back cover 150 between the substrate 110 and the back cover 150. Accordingly, the adhesive reliability of the substrate 110 and the back cover 150 may be improved by the heat dissipation adhesive film 160.

The heat dissipation adhesive film 160 according to the present disclosure may include a base film 161 and a first adhesive film 162 and a second adhesive film 163 disposed on both surfaces of the base film 161. The first adhesive film 162 and the second adhesive film 163 include adhesive resins 162a and 163a and heat dissipation beads 162b and 163b which are dispersed in the adhesive resins 162a and 163a. Accordingly, the heat generated in the display device 100 is discharged to the outside through the heat dissipation beads 162b and 163b so that a heat dissipation characteristic of the display device 100 may be improved.

The adhesiveness of the heat dissipation adhesive film 160 may be reduced after being stretched. Specifically, that is, even though the heat dissipation beads 162b and 163b of the heat dissipation adhesive film 160 maintain an initial shape even after being stretched, the adhesive resins 162a and 163a are stretched so that the thickness thoseof may be reduced. Accordingly, after stretching the heat dissipation adhesive film, surfaces of the first adhesive film 162 and the second adhesive film 163 may have an uneven shape due to the heat dissipation beads 162b and 163b. Further, the adhesive surface area of the first adhesive film 162 and the second adhesive film 163 may be reduced due to the uneven surface. Accordingly, the heat dissipation adhesive film 160 is simply pulled to be stretched so that the heat dissipation adhesive film 160 may be easily separated from the back cover 150 or the substrate 110.

Therefore, when the heat dissipation adhesive film 160 is released from the back cover 150 or the substrate 110, a separate cutting tool may not be used. Accordingly, the heat dissipation adhesive film 160 may be released without causing the damage of the back cover 150 or the substrate 110. Therefore, the back cover 150 and the substrate 110 may be reused so that the rework characteristic may be improved. Further, a material cost may be saved by the rework of the back cover 150 and the substrate 110.

Referring to FIG. 2, a total thickness of the heat dissipation adhesive film 160 may be 50 μm to 150 μm in one embodiment. If the total thickness of the heat dissipation adhesive film 160 is 150 μm or larger, the heat dissipation effect may be reduced.

The thickness of the base film 161 may be 30 μm to 100 μm in one embodiment. If the thickness of the base film 161 is less than 30 μm, the rigidity of the heat dissipation adhesive film 161 may be lowered. If the thickness of the base film 161 is greater than 100 μm, the rigidity of the heat dissipation adhesive film 161 is too large so that the heat dissipation adhesive film 161 may not be sufficiently stretched. Accordingly, it is hard to release the heat dissipation adhesive film 161 so that the rework characteristic of the substrate 110 and the back cover 150 may be lowered.

Thicknesses of the first adhesive film 162 and the second adhesive film 163 may be approximately 10 μm to 25 μm in one embodiment. If the thicknesses of the adhesive films 162 and 163 are 10 μm or smaller, the adhesive characteristic may be lowered due to the small thickness. If the thicknesses of the adhesive films 162 and 163 are 25 μm or larger, as the thickness is increased, the stretching is not sufficiently performed, and the rework characteristic may be degraded. In the meantime, the first adhesive film 162 and the second adhesive film 163 may have the same thickness, but are not limited thereto so that the first adhesive film 162 and the second adhesive film 163 may have different thicknesses.

The first adhesive film 162 and the second adhesive film 163 may have different adhesiveness. The second adhesive film 163 which is in contact with the substrate 110 may be affected by heat generated in the display panel more than that of the first adhesive film 162 which is in contact with the back cover 150. That is, the adhesiveness of the second adhesive film 163 may be lowered due to the heat. Accordingly, the adhesiveness of the second adhesive film 163 is configured to be greater than that of the first adhesive film 162 so that the degradation of the adhesiveness between the display panel and the heat dissipation adhesive film 160 at a high temperature may be avoided.

Further, the adhesiveness of the first adhesive film 162 is less than the adhesiveness of the second adhesive film 163 so that the first adhesive film 162 and the back cover 150 may be easily released from each other. If the adhesiveness of the first adhesive film 162 is equal to the adhesiveness of the second adhesive film 163, the adhesiveness of the first adhesive film 162 is unnecessarily increased so that the back cover 150 may not be easily released therefrom. For example, the first adhesive film 162 and the back cover 150 are firmly bonded so that when the first adhesive film 162 is released from the back cover 150, the first adhesive film 162 is ruptured. Therefore, residuals of the first adhesive film 162 may remain on the back cover 150. Accordingly, the adhesiveness of the first adhesive film 162 is configured to be lower than the adhesiveness of the second adhesive film 163 so that the back cover 150 and the heat dissipation adhesive film 160 may be easily separated.

Specifically, the adhesiveness of the first adhesive film 162 may be 100 gf/inch to 300 gf/inch in one embodiment. If the adhesiveness of the first adhesive film 162 is less than 100 gf/inch, the adhesive characteristic to the back cover 150 may be degraded. If the adhesiveness of the first adhesive film 162 is greater than 300 gf/inch, it is difficult to separate the first adhesive film 162 from the back cover 150 so that the rework characteristic may be degraded.

The adhesiveness of the second adhesive film 163 may be 500 gf/inch to 1500 gf/inch in one embodiment. If the adhesiveness of the second adhesive film 163 is less than 500 gf/inch, the adhesive characteristic to the substrate 110 at a high temperature may be degraded. If the adhesiveness of the second adhesive film 163 is greater than 1500 gf/inch, it is difficult to separate the second adhesive film 163 from the substrate 110 so that the rework characteristic may be degraded.

When the display panel and the back cover 150 are separated, the back cover 150 may be separated first from the display panel to which the heat dissipation adhesive film 160 is attached. Specifically, since the adhesiveness of the first adhesive film 162 is less than the adhesiveness of the second adhesive film 163 so that the back cover 150 may be separated from the first adhesive film 162 first. That after, the heat dissipation adhesive film 160 which is attached to the substrate 110 of the display panel is pulled to be stretched to release the heat dissipation adhesive film 160 from the substrate 110. However, the present disclosure is not limited thereto, and the display panel may be separated from the heat dissipation adhesive film 160 first.

In the meantime, in order to easily separate the heat dissipation adhesive film 160 and the back cover 150, heat may be applied to the heat dissipation adhesive film 160. Generally, the adhesiveness may be degraded in a high temperature and high humidity environment. Further, generally, the lower the modulus, the higher the stretching rate. The modulus of the heat dissipation adhesive film 160 according to the present disclosure may be lowered at a high temperature. Therefore, heat is applied to the heat dissipation adhesive film 160 to simultaneously lower the adhesiveness and reduce the modulus. Specifically, the first adhesive film 162 of the heat dissipation adhesive film 160 which is bonded to the back cover 150 is less adhesive than the second adhesive film 163. Accordingly, heat is applied to effectively lower the adhesiveness of the first adhesive film 162 and the back cover 150 may be easily separated from the display panel to which the heat dissipation adhesive film 160 is attached.

Referring to FIG. 2, the heat dissipation beads 162b may be formed with a circular shape or an elliptical shape. A diameter of the heat dissipation beads 162b and 163b may be equal to or smaller than the thickness of the adhesive films 162 and 163. When the diameter of the heat dissipation beads 162b and 163b is larger than the thickness of the adhesive films 162 and 163, the adhesive area of the adhesive films 162 and 163 is reduced so that the adhesiveness may be degraded. In the meantime, when the heat dissipation beads 162b and 163b have an elliptical shape, the diameter of the heat dissipation beads 162b and 163b may be a diameter in a major axis of the ellipse or a diameter for a minor axis.

In the meantime, even though in FIG. 2, it is illustrated that the diameter of the heat dissipation beads 162b and 163b is smaller than the thickness of the adhesive films 162 and 163, the diameter of the heat dissipation beads 162b and 163b may be equal to the thickness of the adhesive films 162 and 163. Further, the diameters of the heat dissipation beads 162b and 163b may be equal to each other or different from each other. In other words, even though in FIG. 2, it is illustrated that all the diameters of the heat dissipation beads 162b included in the first adhesive film 162 are equal to each other, the diameters of the heat dissipation beads 162b may be different from each other. Further, the diameters of the heat dissipation beads 163b included in the second adhesive film 163 may be equal to each other or different from each other. Further, the diameter of the heat dissipation bead 162b included in the first adhesive film 162 and the diameter of the heat dissipation bead 163b included in the second adhesive film 163 may be equal to each other or different from each other.

Contents of the heat dissipation beads 162b and 163b may be 10 wt % to 20 wt % of the entire adhesive films 162 and 163. That is, the contents of the heat dissipation beads 162b and 163b may be 10 wt % to 20 wt % of each of the first adhesive film 162 and the second adhesive film 163. When the contents of the heat dissipation beads 162b and 163b are less than 10 wt % of the adhesive films 162 and 163, an amount of the heat dissipation beads 162b and 163b is too small so that the heat dissipation effect may be degraded. When the contents of the heat dissipation beads 162b and 163b are greater than 20 wt % of the adhesive films 162 and 163, an amount of the heat dissipation beads 162b and 163b is too much so that the adhesiveness of the adhesive films 162 and 163 may be degraded. Further, when the amount of the heat dissipation beads 162b and 163b is too much, the modulus of the adhesive films 162 and 163 is increased and the stretching rate is lowered, so that it is difficult to release the heat dissipation adhesive film 160 and the rework characteristic may be lowered.

The stretching rate of the heat dissipation adhesive film 160 may be 500% to 1500%. If the stretching rate of the heat dissipation adhesive film 160 is lower than 500%, the stretching rate is too low so that it is difficult to release the heat dissipation adhesive film 160 and the rework characteristic may be lowered. If the stretching rate of the heat dissipation adhesive film 160 is greater than 1500%, the stretching rate is too high so that the reliability of the heat dissipation adhesive film 160 may be lowered. That is, when the stretching rate is too high, the heat dissipation adhesive film 160 is excessively extended and then eventually breaks. Accordingly, it is difficult to release the heat dissipation adhesive film 160 and the rework characteristic may be lowered.

Further, when the heat dissipation adhesive film 160 is 1000% stretched, the adhesiveness of the heat dissipation adhesive film 160 may be reduced by 50% or more. That is, the adhesiveness of the heat dissipation adhesive film 160 may be reduced by 50% or more due to the stretching, so that the heat dissipation adhesive film 160 may be easily released from the back cover 150 or the substrate 110. If the adhesiveness of the heat dissipation adhesive film 160 is reduced by less than 50% due to the stretching, when the heat dissipation adhesive film 160 is released, the adhesive films 162 and 163 are ruptured. Therefore, the residuals of the heat dissipation adhesive film 160 may remain on the back cover 150 or the substrate 110. In this case, the residuals of the heat dissipation adhesive film 160 need to be removed by a separate cutting process, which may cause the damage on the back cover 150 or the display panel. That is, the rework of the back cover 150 or the display panel may be disabled.

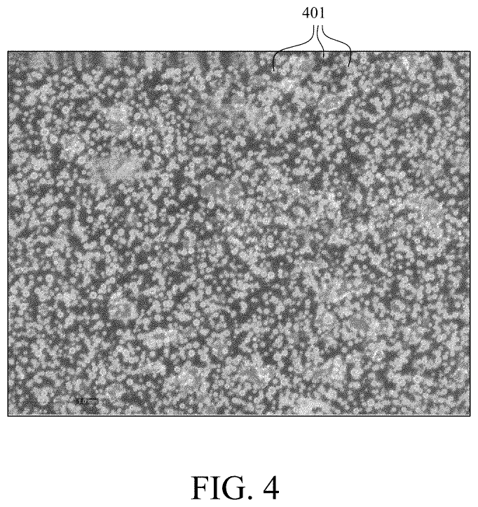

FIG. 4 is an image obtained by photographing a surface of a heat dissipation adhesive film according to an exemplary embodiment of the present disclosure. The image of FIG. 4 is photographed with 50× magnification using Dino Lite.

Referring to FIG. 4, on the surface of the heat dissipation adhesive film, the heat dissipation beads 401 are randomly dispersed in the adhesive resin. At this time, in FIG. 4, bright portions indicate heat dissipation beads and dark portions indicate the adhesive resin. Even though in FIG. 2, the heat dissipation adhesive film 160 is schematically illustrated for the convenience of description, substantially, as illustrated in FIG. 4, heat dissipation beads having various sizes may be randomly dispersed in the adhesive resin. Accordingly, the heat dissipation characteristic of the display device may be improved by the heat dissipation adhesive film including the heat dissipation beads.

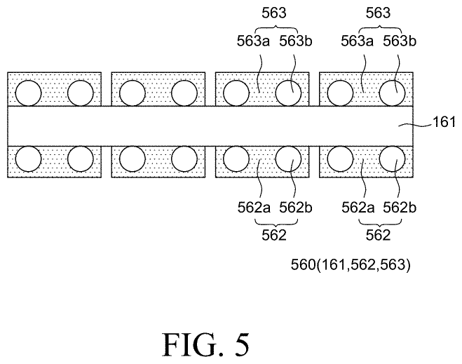

FIG. 5 is a cross-sectional view of a heat dissipation adhesive film according to another exemplary embodiment of the present disclosure. A heat dissipation adhesive film 560 of FIG. 5 is substantially the same as the heat dissipation adhesive film of FIG. 2 excluding a plurality of first sub adhesive films 562 and a plurality of second sub adhesive films 563, so that a redundant description will be omitted.

Referring to FIG. 5, the heat dissipation adhesive film 560 includes a base film 161, a plurality of first sub adhesive films 562 and a plurality of second sub adhesive films 563.

The plurality of first sub adhesive films 562 may be disposed on a lower surface of the base film 161. At this time, the lower surface of the base film 161 may be an area which faces the back cover 150 of the display device 100 of FIG. 1. That is, the heat dissipation adhesive film 560 and the back cover 150 may be attached to each other by the plurality of first sub adhesive films 562. Each of the plurality of first sub adhesive films 562 may include an adhesive resin 562a and heat dissipation beads 562b which are dispersed in the adhesive resin 562a. Here, the adhesive resin 562a and the heat dissipation beads 562b may be the same as the adhesive resins 162a and 163a and the heat dissipation beads 162b and 163b which have been described with reference to FIG. 2.

The plurality of second sub adhesive films 563 may be disposed on an upper surface of the base film 161. At this time, the upper surface of the base film 161 may be an area which faces the substrate 110 of the display device 100 of FIG. 1. That is, the heat dissipation adhesive film 560 and the substrate 110 may be attached to each other by the plurality of second sub adhesive films 563. Each of the plurality of second sub adhesive films 563 may include an adhesive resin 563a and heat dissipation beads 563b which are dispersed in the adhesive resin 563a. Here, the adhesive resin 563a and the heat dissipation beads 563b may be the same as the adhesive resins 162a and 163a and the heat dissipation beads 162b and 163b as described with reference to FIG. 2.

The plurality of first sub adhesive films 562 may be disposed to be spaced apart from each other on the lower surface of the base film 161. The plurality of second sub adhesive films 563 may be disposed to be spaced apart from each other on the upper surface of the base film 161. Specifically, the lower surface and the upper surface of the base film 161 are coated with the adhesive resins 562a and 563a in which the heat dissipation beads 562b and 563b are dispersed and the adhesive resins 562a and 563a are patterned. By doing this, the plurality of first sub adhesive films 562 and the plurality of second sub adhesive films 563 may be formed. The stress applied to the heat dissipation adhesive film 560 at a high temperature may be reduced by a space between the plurality of first sub adhesive films 562 and a space between the plurality of second sub adhesive films 563.

A distance spaced between the plurality of first sub adhesive films 562 and a distance spaced between the plurality of second sub adhesive films 563 may be 5 mm to 10 mm. When the distance is 10 mm or longer, the areas of the adhesive resins 562a and 563a are reduced so that the adhesiveness of the heat dissipation adhesive film 560 may be lowered. When the distance is 5 mm or shorter, the effect of reducing the stress of the heat dissipation adhesive film 560 may be reduced.

In the meantime, even though in FIG. 5, four first sub adhesive films 562 and four second sub adhesive films 563 are disposed, the present disclosure is not limited thereto. Further, a structure of the adhesive films 162 and 163 of FIG. 2 may be applied to any one of the upper surface and the lower surface of the base film 161 and a structure of the adhesive films 562 and 563 of FIG. 5 may be applied to the other of the upper surface and the lower surface of the base film 161.

Further, even though in FIG. 5, the distance spaced between the plurality of first sub adhesive films 562 and the distance spaced between the plurality of second sub adhesive films 563 are the same, the present disclosure is not limited thereto. That is, the distance spaced between the plurality of first sub adhesive films 562 and the distance spaced between the plurality of second sub adhesive films 563 may be configured to be different from each other. For example, the distance spaced between the plurality of first sub adhesive films 562 and the distance spaced between the plurality of second sub adhesive films 563 may be configured to be larger in an area of the heat dissipation adhesive film 560 where more stress is applied. Generally, the stress generated at both side portions of the heat dissipation adhesive film 560 may be larger than the stress generated at the center portion of the heat dissipation adhesive film 560. Accordingly, the distance spaced between the plurality of first sub adhesive films 562 and the distance spaced between the plurality of second sub adhesive films 563 are configured to be larger at both side portions of the heat dissipation adhesive film 560, to relieve the stress applied to the heat dissipation adhesive film 560. However, the present disclosure is not limited thereto.

Further, even though in FIG. 5, widths of the plurality of first sub adhesive films 562 and widths of the plurality of second sub adhesive films 563 are configured to be the same, the present disclosure is not limited thereto. That is, the widths of the plurality of first sub adhesive films 562 and the widths of the plurality of second sub adhesive films 563 may be configured to be different from each other. For example, the widths of the plurality of first sub adhesive films 562 and the widths of the plurality of second sub adhesive films 563 may be smaller in an area of the heat dissipation adhesive film 560 where more stress is applied. That is, the widths of the plurality of first sub adhesive films 562 and the widths of the plurality of second sub adhesive films 563 are configured to be smaller at both side portions of the heat dissipation adhesive film 560, to relieve the stress applied to the heat dissipation adhesive film 560. However, the present disclosure is not limited thereto.

The heat dissipation adhesive film 560 according to another exemplary embodiment of the present disclosure includes a plurality of sub adhesive films 562 and 563 which are disposed on the lower surface or the upper surface of the base film 161 to be spaced apart from each other. Therefore, the stress applied to the sub adhesive films 562 and 563 may be reduced by the space between the plurality of sub adhesive films 562 and 563. That is, the deformation of the heat dissipation adhesive film 560 due to the stress is reduced so that the adhesive reliability between the back cover 150 and the substrate 110 may be improved.

Further, the heat dissipation adhesive film 560 includes heat dissipation beads 562b and 563b to improve the heat dissipation characteristic. Further, the heat dissipation adhesive film 560 is easily separated from the back cover 150 or the substrate 110 so that the back cover 150 or the substrate 110 may be reusable.

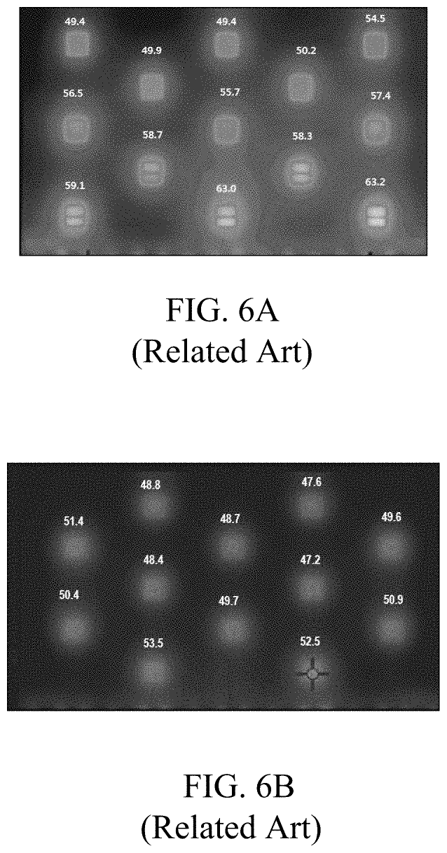

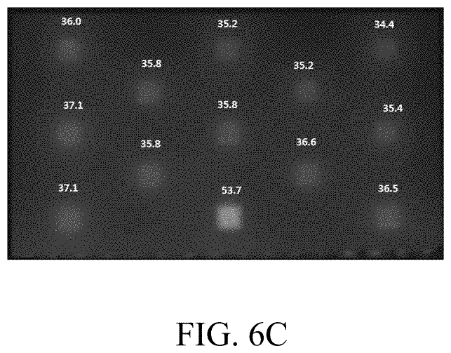

FIGS. 6A to 6C are temperatures of black spot patterns of a display device to which adhesive members according to Comparative Embodiments and Embodiment are applied. FIG. 6A illustrates Comparative Embodiment 1 of related art, FIG. 6B illustrates Comparative Embodiment 2 of related art, and FIG. 6C illustrates Embodiment 1.

In Comparative Embodiment 1, Comparative Embodiment 2, and Embodiment 1, only adhesive members for bonding the display panel and the back cover were configured to be different from each other. Specifically, in Comparative Embodiment 1 shown in FIG. 6A, a foam tape was applied to edges of the display panel and the back cover. In Comparative Embodiment 2 shown in FIG. 6B, a PSA film was applied to the entire surface between the display panel and the back cover. Here, the PSA film was formed by applying acrylate-based adhesive resin on both surfaces of a PET base member. In Embodiment 1 shown in FIG. 6C, the heat dissipation adhesive film of FIG. 2 was applied. Both the thicknesses of the PSA film of Comparative Embodiment 2 and the heat dissipation adhesive film of Embodiment 1 were 100 μm.

Table 1 represents a maximum value Max, a minimum value Min, a difference ΔT of the maximum value and the minimum value, and an average according to a result of measuring temperatures (° C.) in FIGS. 6A to 6C.

TABLE 1

| | Comparative | Comparative | |
|---|---|---|---|
| | Embodiment 1 | Embodiment 2 | Embodiment 1 |
| Max | 63.0 | 53.5 | 53.7 |
| Min | 49.4 | 47.2 | 34.4 |
| AT | 13.6 | 6.3 | 19.3 |
| Average | 55.8 | 49.9 | 37.3 |

Referring to FIGS. 6A to 6C and Table 1, the maximum value and the minimum value in Embodiment 1 are lower than those of Comparative Embodiment 1 and Comparative Embodiment 2. Specifically, an average temperature of a black spot pattern of Embodiment 1 was 37.3° C., which was lower than average temperatures of Comparative Embodiment 1 and Comparative Embodiment 2. That is, it was understood that the heat dissipation characteristic of Embodiment 1 was excellent more than those of Comparative Embodiment 1 and Comparative Embodiment 2. Accordingly, the heat dissipation adhesive film according to the present disclosure includes the heat dissipation beads so that the heat dissipation characteristic of the display device may be improved.

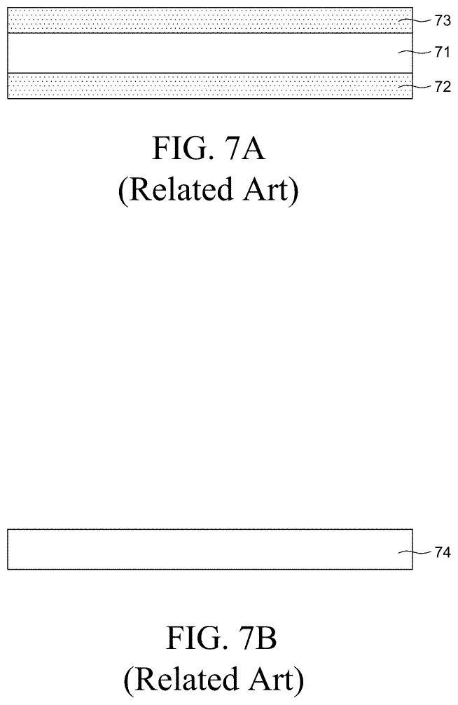

FIGS. 7A and 7B are cross-sectional views of an adhesive member according to Comparative Embodiments of related art. FIG. 7A illustrates the above-mentioned PSA film according to Comparative Embodiment 2 and FIG. 7B illustrates Comparative Embodiment 3.

Referring to FIG. 7A, an adhesive member according to Comparative Embodiment 2 includes a base film 71, a first adhesive film 72, and a second adhesive film 73. At this time, the base film 71 may be formed by PET. Further, the first adhesive film 72 and the second adhesive film 73 may be formed of acrylate-based resin. Since the base film 72 is formed by PET, it may be advantageous to ensure the rigidity of the adhesive member.

Referring to FIG. 7B, the adhesive member 74 according to Comparative Embodiment 3 may be configured by a rubber-based PSA. Therefore, the adhesive member 74 may have a high stretching rate. Specifically, the adhesive member 74 may be configured by a resin including 65 to 75 parts by weight of a butadiene-based resin, 15 to 25 parts by weight of tackifier, 2.5 to 7.5 parts by weight of an anti-aging agent, and 2.5 to 7.5 parts by weight of a heat-resistant polymer.

Table 2 represents characteristics of the adhesive members according to Comparative Embodiment 2, Comparative Embodiment 3, Comparative Embodiment 4, and Embodiment 1. Here, rework indicates whether to rework the back cover and the substrate by heating (80° C.) and releasing the back cover and the substrate (the encapsulating substrate 960 of FIG. 9 in a case of the bottom emission type) to which adhesive members are attached. In the meantime, Comparative Embodiment 4 and Embodiment 1 are configured to be the same as the heat dissipation adhesive film 160 of FIG. 2 excepting the content of the heat dissipation beads.

TABLE 2

| | | Comp. | Comp. | Comp. | |
|---|---|---|---|---|---|
| | | Embodiment 2 | Embodiment 3 | Embodiment 4 | Embodiment 1 |
| Heat dissipation bead | | X | X | 30 | 20 |
| content (Weight %) | | | | | |
| Adhesiveness | Substrate | 1100 | 750 | 880 | 1020 |
| (gf/inch) | (Panel) | | | | |
| | Back | 120 | | 260 | 240 |
| | cover | | | | |
| Modulus | 25° C. | 4.07 × 10⁸ | 3.25 × 10⁶ | 3.25 × 10⁶ | 1.30 × 10⁷ |
| (Pa) | 80° C. | 4.53 × 10⁸ | 1.80 × 10⁶ | 7.26 × 10⁴ | 5.51 × 10⁶ |

| | | | | |
|---|---|---|---|---|
| Stretching rate (%) | 65 | 1975 | 1075 | 1100 |
| Rework | X | X | Δ (Broken) | O |

Comparative Embodiment 2, Comparative Embodiment 4, and Embodiment 1 have a structure in which a first adhesive film and a second adhesive film are disposed on the lower surface and the upper surface of the base member so that the adhesiveness of the first adhesive film and the second adhesive film may be different from each other. Specifically, the adhesiveness of the first adhesive film which is bonded to the back cover may be lower than the adhesiveness of the second adhesive film which is bonded to the substrate of the display panel. In Comparative Embodiment 3, the adhesive member is configured as a single layer so that an area bonded to the back cover and an area bonded to the substrate may have the same adhesiveness.

Generally, the higher the modulus, the lower the stretching rate and the lower the modulus, the higher the stretching rate. When the modulus is too high or the stretching rate is too low, the adhesive member is not satisfactorily extended, so that it may be difficult to cleanly release the adhesive member from the back cover or the substrate. Further, when the modulus is too low or the stretching rate is too high, the adhesive member is excessively extended so that the adhesive member is not satisfactorily released and may be broken. When the adhesive member is not satisfactorily released from the back cover or the substrate, the adhesive member needs to be removed by a separate cutting process. Therefore, the back cover or the panel is damaged so that the back cover or the panel may not be reworked.

In Comparative Embodiment 2, the PET base member is included so that the rigidity is high. Therefore, the highest modulus and the lowest stretching rate are obtained. In Comparative Embodiment 3, the adhesive member is configured by rubber-based PSA, so that the modulus is low and the stretching rate is the highest. Therefore, it is confirmed that according to Comparative Embodiment 2 and Comparative Embodiment 3, the adhesive member is not smoothly released so that the rework is not possible.

In Comparative Embodiment 4, as compared with Embodiment 1, the content of heat dissipation beads is high so that the adhesiveness is somewhat low. Further, it is confirmed that in Comparative Embodiment 4 and Embodiment 1, the stretching rates are similar, but at a high temperature (80° C.), the modulus of Comparative Embodiment 4 is significantly lowered. Accordingly, it is confirmed that the adhesive member is excessively extended and is ruptured, so that the rework is difficult.

That is, referring to FIG. 2, it is confirmed that Embodiment 1 of FIG. 2 according to the present disclosure is the most excellent in terms of rework.

In Table 3, adhesiveness of Comparative Embodiment 2, Comparative Embodiment 3, and Embodiment 1 before and after stretching the adhesive member are compared. At this time, the adhesiveness was measured using TAC-II of RHESCA.

TABLE 3

| | Comparative | Comparative | Embodiment |
|---|---|---|---|
| | Embodiment 2 | Embodiment 3 | 1 |
| Adhesiveness | 305 | 312 | 298 |
| (before stretching) | | | |
| (gf/inch) | | | |
| Adhesiveness | 302 | 278 | 30 |
| (after stretching) | | | |
| (gf/inch) | | | |

Referring to Table 3, in Comparative Embodiment 2 and Comparative Embodiment 3, the adhesiveness before and after stretching are similar. In contrast, it is confirmed that in Embodiment 1, the adhesiveness after stretching is reduced to approximately one tenth of the adhesiveness before stretching. That is, in Embodiment 1, the adhesive surface area of the heat dissipation adhesive film after being stretched may be reduced due to the heat dissipation beads. Accordingly, the heat dissipation adhesive film may be easily released from the back cover or the substrate and the back cover or the substrate may be reusable after releasing the heat dissipation adhesive film.

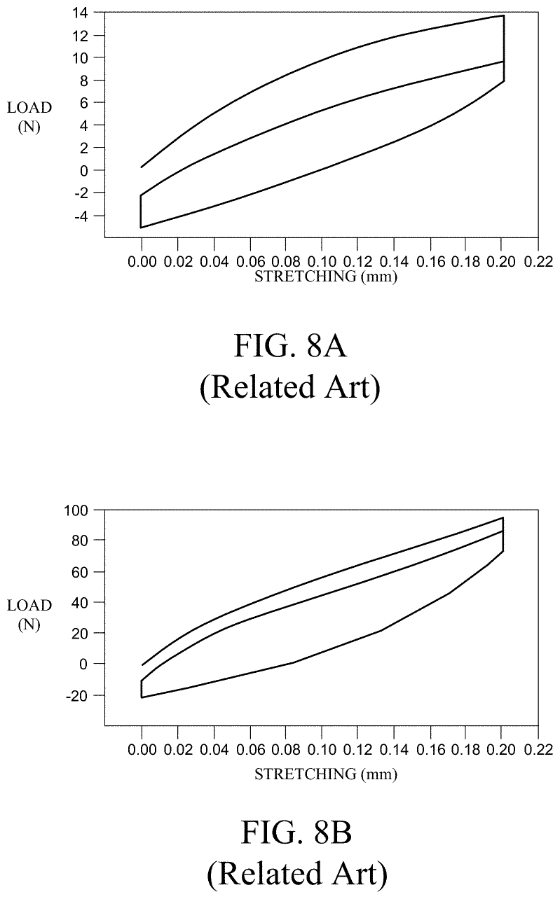

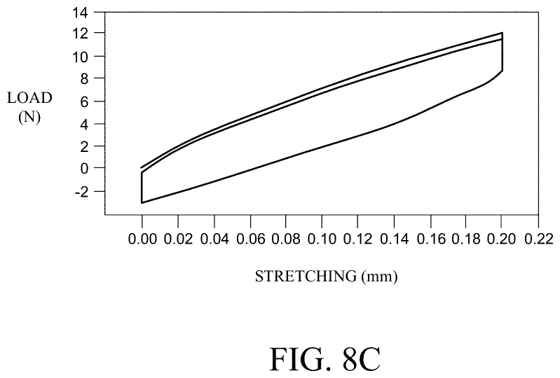

FIGS. 8A to 8C are restoring force evaluation results of adhesive members according to Comparative Embodiments of related art and the Embodiment. Specifically, FIG. 8A illustrates Comparative Embodiment 2, FIG. 8B illustrates Comparative Embodiment 3, and FIG. 8C illustrates Embodiment 1. Thicknesses of the adhesive members of Comparative Embodiment 2, Comparative Embodiment 3, and Embodiment 1 were 100 μm.

As equipment for evaluating a restoring force, UTM 5969 was used. An evaluation sample for evaluating a restoring force was configured by disposing adhesive members of Comparative Embodiment 2, Comparative Embodiment 3, and Embodiment 1 between a SUS substrate (corresponding to the substrate of the display panel) and an aluminum substrate (corresponding to the back cover). The evaluation was performed in the order of stretching by 0.20 mm, holding for three minutes, stretching by −0.20 mm, and holding for three minutes. At this time, the stretching speed was set to 0.1 mm/minute. Further, the results of FIGS. 8A to 8C were represented with respect to an expansion gap of the SUS substrate and the aluminum substrate at a temperature of 60° C. and a humidity of 90%.

Table 4 represents values of the restoring forces of Comparative Embodiment 2, Comparative Embodiment 3, and Embodiment 1 according to a restoring force evaluation result.

TABLE 4

| | Comparative | Comparative | |
|---|---|---|---|
| | Embodiment 2 | Embodiment 3 | Embodiment 1 |
| Restoring force (%) | 16.3 | 10 | 4.8 |

Generally, the lower the value of the restoring force, the less the changed amount before and after stretching. Accordingly, the lower the value of the restoring force, the less the deformation of the adhesive member and the higher the reliability of the adhesive member.

Referring to FIGS. 8A to 8C and Table 4, the changed amount of Embodiment 1 is smaller than those of Comparative Embodiment 2 and Comparative Embodiment 3, and the restoring force of Embodiment 1 was lower than those of Comparative Embodiment 2 and Comparative Embodiment 3. That is, it is understood that according to Embodiment 1, the deformation due to external elements is small so that the high reliability and excellent characteristic are obtained as compared with Comparative Embodiment 2 and Comparative Embodiment 3.

In Table 5, a high temperature reliability deformation amount (mm) according to Embodiment 1 and Embodiment 2 is compared. Embodiment 1 is for the heat dissipation adhesive film 160 of FIG. 2 and Embodiment 2 is for the heat dissipation adhesive film 560 of FIG. 5. At this time, the upper surface refers to an area corresponding to the display panel and the lower surface refers to an area corresponding to the back cover.

Specifically, evaluation samples according to Embodiment 1 and Embodiment 2 were placed in a high temperature (60° C.) and high humidity (90%) chamber for 240 hours and then a deformed amount at a room temperature was measured. The evaluation sample was configured by disposing the heat dissipation adhesive films of Embodiment 1 and Embodiment 2 between a glass substrate (corresponding to the substrate 110 or the encapsulating substrate 960 of the display panel) and an ACM substrate (corresponding to the back cover). At this time, a size of the evaluation sample was 770×455×3.2 mm

TABLE 5

| | Embodiment 1 | | Embodiment 2 | |
|---|---|---|---|---|
| | Upper surface | Lower surface | Upper surface | Lower surface |
| Initial | −1 | 0 | −1 | −0.5 |
| 5 minutes | −0.5 | 0.5 | −0.5 | 0 |
| 10 minutes | 1 | 1 | 0 | 0 |
| 30 minutes | 1.5 | 1 | 0 | 0.5 |
| 60 minutes | 2.5 | 1.4 | 0 | 0.5 |
| Deformed | 3.5 | 1.4 | 1 | 1 |
| amount | | | | |

Referring to Table 5, it was confirmed that a deformed amount of Embodiment 2 was lower than a deformed amount of Embodiment 1. When the heat dissipation adhesive film was disposed so as to correspond to the entire area between the substrate and the back cover, a stress was generated in the display device so that the display device may be slightly bent at a high temperature. In Embodiment 2, the heat dissipation adhesive film includes a plurality of sub adhesive films which is spaced apart from each other by the patterning. Accordingly, the stress is relieved due to the space between the plurality of sub adhesive films and the bending of the display device may be minimized.

FIG. 9 is a is a cross-sectional view of a display device according to another exemplary embodiment of the present disclosure. The display device 900 of FIG. 9 is a bottom emission type display device 900. The display device 900 of FIG. 9 is substantially the same as the display device 100 of FIG. 1 excluding a pixel unit 920, an encapsulating layer 940, an adhesive layer 950 and an encapsulating substrate 960, so that a redundant description will be omitted.

Referring to FIG. 9, the display device 900 includes the substrate 110, the pixel unit 920, the encapsulating layer 940, the adhesive layer 950, the encapsulating substrate 960, the heat dissipation adhesive film 160 and the back cover 150.

The pixel unit 920 is disposed on the substrate 110. The pixel unit 920 includes the plurality of light emitting diodes and a circuit for driving the light emitting diodes. The pixel unit 920 may include the transistor 120 of FIG. 1 and the light emitting diode of FIG. 1.

The encapsulating layer 940 which covers the pixel unit 920 is disposed on the pixel unit 920. The encapsulating layer 940 seals the light emitting diode of the pixel unit 920. The encapsulating layer 940 may protect the light emitting diode of the pixel unit 920 from moisture, oxygen, and impacts of the outside. The encapsulating layer 940 may be formed by alternately laminating a plurality of inorganic layers and a plurality of organic layers, but is not limited thereto. For example, the encapsulating layer 940 may be corresponded to the encapsulating unit 140 of FIG. 1.

The encapsulating substrate 960 is disposed on the encapsulating layer 940. The encapsulating substrate 960 protects the light emitting diode of the pixel unit 920 together with the encapsulating layer 940. The encapsulating substrate 960 may protect the light emitting diode of the pixel unit 920 from moisture, oxygen, and impacts of the outside. The encapsulating substrate 960 may be formed of a metal material, which has a high corrosion resistance and is easily processed in the form of a foil or a thin film, such as aluminum (Al), nickel (Ni), chromium (Cr), and an alloy material of iron (Fe) and nickel, but is not limited thereto.

The adhesive layer 950 may be disposed between the encapsulation layer 940 and the encapsulation substrate 960. The adhesive layer 950 may bond the encapsulating layer 940 and the encapsulating substrate 960 to each other. The adhesive layer 950 may include one or more adhesive layers. The adhesive layer 950 is formed of a material having adhesiveness and may be a thermosetting or natural curable type adhesive. For example, the adhesive layer 950 may be formed of an optical clear adhesive (OCA) or a pressure sensitive adhesive (PSA), but is not limited thereto.

In the meantime, the adhesive layer 950 may be disposed to enclose the encapsulating layer 940 and the pixel unit 920. That is, the pixel unit 920 may be sealed by the encapsulating layer 940, and the encapsulating layer 940 and the pixel unit 920 may be sealed by the adhesive layer 950. The adhesive layer 950 may protect the light emitting diode of the pixel unit 920 from moisture, oxygen, and impacts of the outside together with the encapsulating layer 940 and the encapsulating substrate 960. In this case, the adhesive layer 950 may further include an absorbent. The absorbent may be particles having hygroscopicity and absorb moisture and oxygen from the outside to reduce permeation of the moisture and oxygen into the pixel unit 920.

The back cover 150 may be disposed on the encapsulating substrate 960. Further, the heat dissipation adhesive film 160 may be disposed between the back cover 150 and the encapsulating substrate 960.

The exemplary embodiments of the present disclosure may also be described as follows:

According to an aspect of the present disclosure, a heat dissipation adhesive film includes: a base film; a first adhesive film on a lower surface of the base film, and a second adhesive film on an upper surface of the base film, and the first adhesive film or the second adhesive film includes an adhesive resin and heat dissipation beads dispersed in the adhesive resin.

According to another aspect of the present disclosure, a diameter of the heat dissipation bead may be equal to or smaller than a thickness of the first adhesive film or the second adhesive film.

According to still another aspect of the present disclosure, a content of the heat dissipation beads in the first adhesive film or the second adhesive film may be 10 wt % to 20 wt %.

According to still another aspect of the present disclosure, a thickness of the base film may be 30 μm to 100 μm, and the thickness of each of the first adhesive film and the second adhesive film may be 10 μm to 25 μm.

According to still another aspect of the present disclosure, an adhesiveness of the first adhesive film and an adhesiveness of the second adhesive film may be different from each other.

According to still another aspect of the present disclosure, a stretching rate of the heat dissipation adhesive film may be 500% to 1500%.

According to still another aspect of the present disclosure, the base film may include a urethane-based or butadiene-based rubber.

According to still another aspect of the present disclosure, the adhesive resin may include an acrylate-based or urethane-based resin

According to still another aspect of the present disclosure, when the heat dissipation adhesive film is 1000% stretched, the adhesiveness of the heat dissipation adhesive film may be reduced by 50% or more.

According to still another aspect of the present disclosure, the first adhesive film or the second adhesive film may include a plurality of sub adhesive films which is spaced apart from each other.

According to another aspect of the present disclosure, a display device includes a substrate, a light emitting diode on the substrate, a back cover below the substrate, and a heat dissipation adhesive film which bonds the back cover and the substrate, the heat dissipation adhesive film includes a base film; a first adhesive film between the base film and the back cover, and a second adhesive film between the base film and the substrate, and the first adhesive film or the second adhesive film includes an adhesive resin and heat dissipation beads dispersed in the adhesive resin.

According to another aspect of the present disclosure, a stretching rate of the heat dissipation adhesive film may be 500% to 1500%.

According to still another aspect of the present disclosure, when the heat dissipation adhesive film is 1000% stretched, the adhesiveness of the heat dissipation adhesive film may be reduced by 50% or more.

According to still another aspect of the present disclosure, a thickness of the base film may be 30 μm to 100 μm, and the thickness of each of the first adhesive film and the second adhesive film may be 10 μm to 25 μm.

According to still another aspect of the present disclosure, an adhesiveness of the first adhesive film and an adhesiveness of the second adhesive film may be different from each other.

According to still another aspect of the present disclosure, a diameter of the heat dissipation bead may be equal to or smaller than a thickness of the first adhesive film or the second adhesive film.

According to still another aspect of the present disclosure, a content of the heat dissipation beads in the first adhesive film or the second adhesive film may be 10 wt % to 20 wt %.

According to still another aspect of the present disclosure, the first adhesive film or the second adhesive film may include a plurality of sub adhesive films which is spaced apart from each other.

According to still another aspect of the present disclosure, the base film may include a urethane-based or butadiene-based rubber.

According to still another aspect of the present disclosure, the adhesive resin may include an acrylate-based or urethane-based resin

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A heat dissipation adhesive film, comprising:
a base film;
a first adhesive film on a lower surface of the base film; and
a second adhesive film on an upper surface of the base film;
wherein at least one of the first adhesive film and the second adhesive film includes an adhesive resin and heat dissipation beads dispersed in the adhesive resin.

2. The heat dissipation adhesive film according to claim 1, wherein a diameter of the heat dissipation beads is equal to or less than a thickness of the first adhesive film or a thickness of the second adhesive film.

3. The heat dissipation adhesive film according to claim 1, wherein a content of the heat dissipation beads in the first adhesive film or the second adhesive film is 10 wt % to 20 wt %.

4. The heat dissipation adhesive film according to claim 1, wherein a thickness of the base film is 30 μm to 100 μm, and a thickness of each of the first adhesive film and the second adhesive film is 10 μm to 25 μm.

5. The heat dissipation adhesive film according to claim 1, wherein an adhesiveness of the first adhesive film is different from an adhesiveness of the second adhesive film.

6. The heat dissipation adhesive film according to claim 1, wherein a stretching rate of the heat dissipation adhesive film is 500% to 1500%.

7. The heat dissipation adhesive film according to claim 1, wherein the base film includes a urethane-based rubber or a butadiene-based rubber.

8. The heat dissipation adhesive film according to claim 1, wherein the adhesive resin includes an acrylate-based resin or a urethane-based resin.

9. The heat dissipation adhesive film according to claim 1, wherein when the heat dissipation adhesive film is 1000% stretched, an adhesiveness of the heat dissipation adhesive film is reduced by 50% or more.

10. The heat dissipation adhesive film according to claim 1, wherein at least one of the first adhesive film and the second adhesive film includes a plurality of sub adhesive films which are spaced apart from each other.

11. A display device, comprising:
a display panel,
a back cover, and
a heat dissipation adhesive film which bonds together the back cover and the display panel,
wherein the heat dissipation adhesive film includes:
a base film;
a first adhesive film on a lower surface of the base film; and
a second adhesive film on a upper surface of the base film,
wherein at least one of the first adhesive film and the second adhesive film includes an adhesive resin and heat dissipation beads dispersed in the adhesive resin.

12. The display device according to claim 11, wherein a stretching rate of the heat dissipation adhesive film is 500% to 1500%.

13. The display device according to claim 11, wherein when the heat dissipation adhesive film is 1000% stretched, an adhesiveness of the heat dissipation adhesive film is reduced by 50% or more.

14. The display device according to claim 11, wherein a thickness of the base film is 30 μm to 100 μm, and a thickness of each of the first adhesive film and the second adhesive film is 10 μm to 25 μm.

15. The display device according to claim 11, wherein an adhesiveness of the first adhesive film is different from an adhesiveness of the second adhesive film.

16. The display device according to claim 11, wherein a diameter of the heat dissipation bead is equal to or smaller than a thickness of the first adhesive film or a thickness of the second adhesive film.

17. The display device according to claim 11, wherein a content of the heat dissipation beads in the first adhesive film or the second adhesive film is 10 wt % to 20 wt %.

18. The display device according to claim 11, wherein at least one of the first adhesive film and the second adhesive film includes a plurality of sub adhesive films which are spaced apart from each other.

19. The display device according to claim 11, wherein the base film includes a urethane-based rubber or a butadiene-based rubber.

20. The display device according to claim 11, wherein the adhesive resin includes an acrylate-based resin or a urethane-based resin.
